(19) United States
(12) Patent Application Publication
(10) Pub. No.: US 2008/0122063 A1
(43) Pub. Date: May 29, 2008

(54) Semiconductor device

(75) Inventor: Takashi Akiba, Tochigi (JP)

Correspondence Address: MORRISON & FOERSTER LLP, 1650 TYSONS BOULEVARD, SUITE 400, MCLEAN, VA, 22102, US

(73) Assignee: SANYO ELECTRIC CO., LTD., Moriguchi-shi (JP)

(21) Appl. No.: 11/819,162

(22) Filed: Jun. 25, 2007

(30) Foreign Application Priority Data
Jun. 26, 2006 (JP) 2006-175278

(51) Int. Cl. H01L 23/50

(52) U.S. Cl. 257/691; 257/E23.079

(57) ABSTRACT

A conventional semiconductor device has a problem that power-conversion energy efficiency in a DC-DC converter circuit is influenced by MOSFET characteristics. In a semiconductor device of the present invention, three MOSFET elements are fixed onto a die pad. Moreover, source electrodes of the MOSFET elements are commonly connected to one another with a conductive plate. Furthermore, drain electrodes of the MOSFET elements are commonly connected to one another. Meanwhile, gate electrodes of the MOSFET elements are individually connected. This structure allows the MOSFET elements to be individually driven according to purposes.

Priority is claimed to Japanese Patent Application Number JP2006-175278 filed on Jun. 26, 2006, the disclosure of which is incorporated herein by reference in its entirety.

### BACKGROUND OF THE INVENTION

1. Field of the Invention

The present invention relates to a semiconductor device in which a plurality of semiconductor elements are sealed in one package, and which allows characteristics of the semiconductor elements to be improved.

2. Description of the Related Art

As an example of a conventional semiconductor device, the following power semiconductor device package is known. Specifically, a first power MOSFET chip and a second power MOSFET chip are formed into a laminated structure. Moreover, the MOSFET chips are connected to each other in parallel, and are integrally sealed with resin. The first and second power MOSFET chips have electrically the same structure. A source electrode and a gate electrode are formed on a front surface of each chip, and a drain electrode is formed on a rear surface of each chip. Moreover, the first power MOSFET chip is fixed onto a lead frame by use of solder. The front surface of the second power MOSFET chip is disposed on the first power MOSFET chip. An electrode-wiring metal plate is disposed between the two chips. Via the electrode wiring metal plate, the source electrodes are fixed to each other, and the gate electrodes are fixed to each other. Note that the drain electrode of the second power MOSFET chip is electrically connected, via a metal frame, to the lead frame to which the drain electrode of the first power MOSFET chip is fixed. This technology is described for instance in Japanese Patent Application Publication No. 2005-302951 (Pages 3 and 4, FIGS. 1 and 2).

In the conventional semiconductor device, as described above, the first and second power MOSFET chips having electrically the same structure are connected to each other in parallel, and are driven at the same timing in response to the same control signal sent to the gate electrodes thereof. This structure can achieve a power semiconductor device package having a low on-resistance value and a large rated current while avoiding an increase in a package size. However, for example, in a case where the semiconductor device is used in a DC-DC converter circuit, there is a problem that, in a low-current region, the semiconductor device has such a large capacity that power-conversion energy efficiency is lowered since the first and the second MOSFET chips are driven at the same timing.

### SUMMARY OF THE INVENTION

The present invention has been made in consideration of the foregoing circumstances. A semiconductor device of the present invention is one in which a plurality of semiconductor elements are sealed, as integrally connected to one another, in one package. Here, each semiconductor element is provided with a main electrode formed at one principal surface that mainly supplies a principal current, and a control electrode formed at one principal surface that sends and receives a control signal. The semiconductor device includes a conductive plate connected integrally to the main electrodes of the respective plurality of semiconductor elements, and conductive members connected to the control electrodes of the plurality of semiconductor elements on a one-to-one basis. Hence, in the present invention, the common conductive plate is fixed to the main electrodes of the plurality of semiconductor elements as integrally connected to one another. Moreover, the conductive members are connected to the control electrodes of the semiconductor elements on a one-to-one basis. This structure makes it possible to individually drive the plurality of semiconductor elements, and thus to improve efficiency by changing a current amount according to purposes.

Additionally, the present invention provides a semiconductor device in which a plurality of semiconductor chips are sealed in one package. Here, each semiconductor chip is provided with a main electrode formed at one principal surface that mainly supplies a principal current, and a control electrode formed at one principal surface that sends and receives a control signal. The semiconductor device includes a conductive plate connected integrally to the main electrodes of the respective plurality of semiconductor chips, and conductive members connected to the control electrodes of the plurality of semiconductor chips on a one-to-one basis. Hence, in the present invention, the common conductive plate is fixed to the main electrodes of the plurality of semiconductor chips. Moreover, the conductive members are connected to the control electrodes of the plurality of semiconductor chips on a one-to-one basis. This structure makes it possible to improve efficiency by individually driving the plurality of semiconductor chips, and by changing a current amount according to purposes.

Moreover, the semiconductor device of the present invention includes that the conductive plate has a flat-plate shape. Accordingly, the present invention makes it possible to reduce the thickness of the package with the flat-plate shape of the conductive plate.

Moreover, the semiconductor device of the present invention includes that the conductive plate has solder wettability only in a region where the conductive plate is connected to the main electrodes of the respective semiconductor elements. Thus, the present invention makes it possible to fix the conductive plate to the main electrodes of the semiconductor elements by use of a self-alignment technique utilizing the solder wettability.

Moreover, the semiconductor device of the present invention includes that a plurality of concave and convex shapes are formed on the conductive plate. Moreover, the main electrodes of the respective semiconductor chips are connected to concave regions of the conductive plate. Thus, the present invention can prevent the conductive plate from being in contact with edges of the respective semiconductor chips by forming the plurality of concave parts on the conductive plate, which concave parts correspond to the respective main electrodes of the semiconductor chips.

Moreover, the semiconductor device of the present invention includes that the conductive members are thin metal wires. Thus, the present invention makes it possible to individually drive the plurality of semiconductor elements according to purposes.

### BRIEF DESCRIPTION OF THE DRAWINGS

FIG. 1 is a plan view for explaining a semiconductor device according to a preferred embodiment of the present invention.

FIG. 2A is a cross-sectional view taken along the line A-A in FIG. 1, and FIG. 2B is a cross-sectional view taken along the line B-B in FIG. 1, both for explaining the semiconductor device according to the preferred embodiment of the present invention.

FIGS. 3A and 3B are graphs for explaining power-conversion energy efficiency in a DC-DC converter circuit using the semiconductor device according to the preferred embodiment of the present invention.

FIG. 4 is a plan view for explaining a semiconductor device according to a preferred embodiment of the present invention.

FIG. 5A is a cross-sectional view taken along the line C-C in FIG. 4, and FIG. 5B is a cross-sectional view taken along the line D-D in FIG. 4, both for explaining the semiconductor device according to the preferred embodiment of the present invention.

### DESCRIPTION OF THE EMBODIMENTS

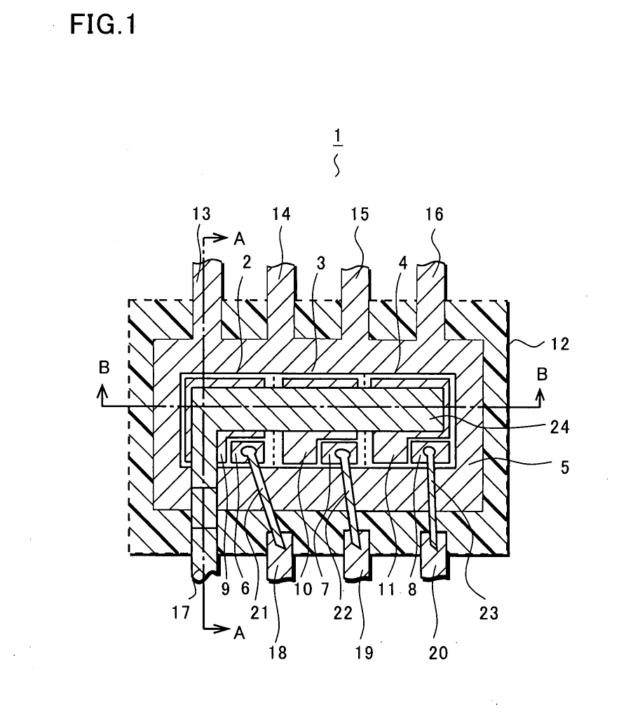

With reference to FIGS. 1 to 3, a semiconductor device according to a preferred embodiment of the present invention will be described in detail below.

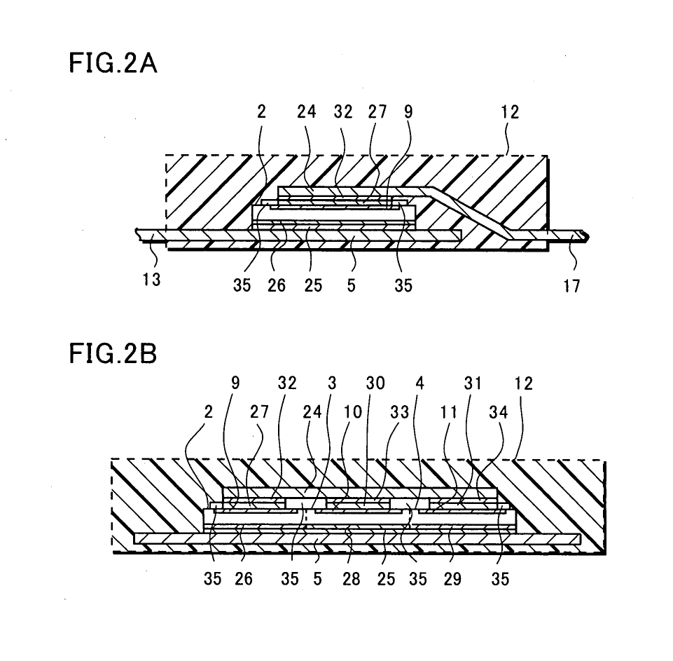

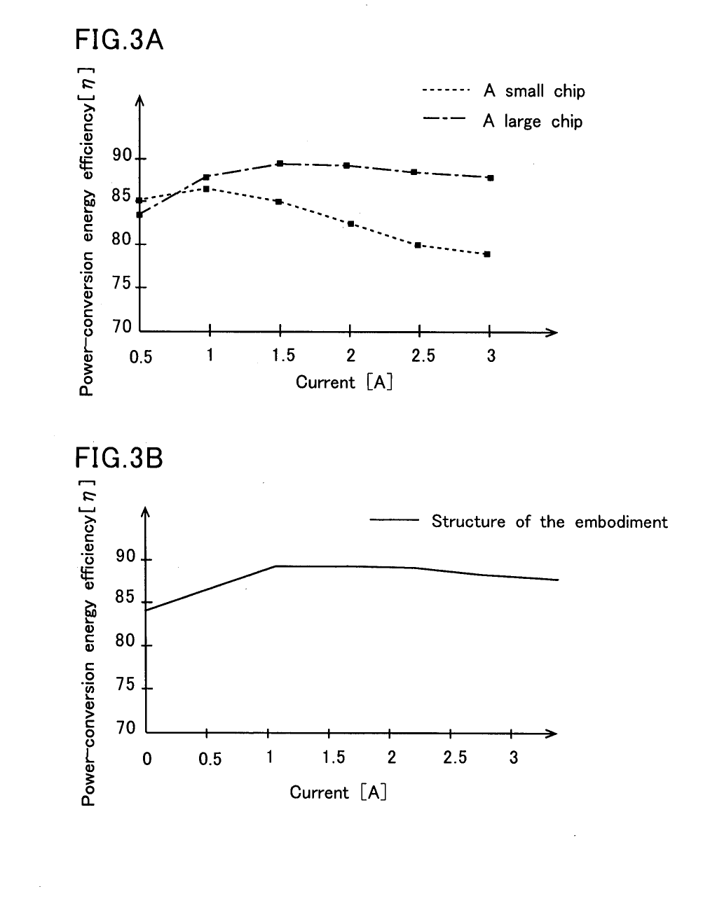

FIG. 1 is a plan view for explaining the semiconductor device according to this embodiment. FIG. 2A is a cross-sectional view taken along the line A-A in the semiconductor device shown in FIG. 1. FIG. 2B is a cross-sectional view taken along the line B-B in the semiconductor device shown in FIG. 1. FIGS. 3A and 3B are graphs for explaining power-conversion energy efficiency in a DC-DC converter circuit using the semiconductor device according to this embodiment. Note that FIG. 1 does not show a passivation film shown in FIGS. 2A and 2B.

As shown in FIG. 1, in a semiconductor device 1 of this embodiment, for example, three MOSFET elements 2 to 4 are fixed to a die pad 5 by use of a conductive adhesive, for example, a conductive paste 25 (see FIG. 2A) such as a solder paste and a silver paste. The MOSFET elements 2 to 4 have the same cell structure and the same element size. Moreover, the MOSFET elements 2 to 4 are integrally connected to one another to form one chip. On a front surface of the chip, gate electrodes 6 to 8 and source electrodes 9 to 11 are formed. Moreover, on a rear surface of the chip, drain electrodes 26, 28 and 29 (see FIG. 2B) are formed. Furthermore, the dotted line shows an external shape of one package 12, and leads 13 to 20 are drawn out of the one package 12, and then are used as external terminals. Specifically, in the semiconductor device 1, a plurality of semiconductor elements, for example, the three MOSFET elements 2 to 4 are sealed in the one package 12.

The die pad 5 and the leads 13 to 20 are formed by processing a copper (Cu) lead frame (hereinafter called a Cu frame). The leads 13 to 16 are formed as being continuous with the die pad 5. The die pad 5 is fixed to the drain electrodes 26, 28 and 29 in the respective MOSFET elements 2 to 4, and the leads 13 to 16 are used as drain terminals. Note that, although the drain electrodes 26, 28 and 29 are formed in the individual MOSFET elements 2 to 4, respectively, the MOSFET elements 2 to 4 are integrated to one another, and thus the drain electrodes 26, 28 and 29 are also integrated to one another. Moreover, a common potential is applied to the drain electrodes 26, 28 and 29 with the die pad 5.

The gate electrode 6 in the MOSFET element 2 is electrically connected to the lead 18 with a thin metal wire 21, and the lead 18 is used as a gate terminal. Similarly, the gate electrodes 7 and 8 in the MOSFET elements 3 and 4 are electrically connected to the leads 19 and 20 with thin metal wires 22 and 23, respectively. The leads 19 and 20 are used as gate terminals.

The source electrodes 9 to 11 in the MOSFET elements 2 to 4 are fixed to a conductive plate 24 made of a conductive material, such as the Cu frame, by use of a conductive adhesive, for example, solder pastes 27, 30 and 31 (see FIG. 2B). Although the MOSFET elements 2 to 4 respectively have the individually independent source electrodes 9 to 11, a common potential is applied to the source electrodes 9 to 11 with the conductive plate 24. Moreover, the lead 17 drawn out of the conductive plate 24 is used as a source terminal.

The structure described above makes it possible to apply common drain potential and common source potential to the MOSFET elements 2 to 4 sealed in the one package 12. Meanwhile, gate potential can be respectively applied to the MOSFET elements 2 to 4. As a result, the MOSFET elements 2 to 4 in the one package 12 can be individually driven. Thus, it is possible to improve efficiency (see descriptions for FIGS. 3A and 3B to be described later) by controlling the amount of currents outputted from the one package 12.

As shown in FIG. 2A, the drain electrode 26 of the MOSFET element 2 is fixed to an upper surface of the die pad 5 by use of the conductive paste 25. Moreover, on an upper surface of the MOSFET element 2, a passivation film 35 made of, for example, a silicon nitride film (SiN) is formed. The source electrode 9 of the MOSFET element 2 is exposed from an opening provided in the passivation film 35. Moreover, by use of the solder paste 27, the conductive plate 24 is fixed to an upper surface of the source electrode 9 of the MOSFET element 2. On a bonded surface of the conductive plate 24, a thin metal film 32 having high solder wettability is formed, by use of a plating method or the like, at least in a region fixed to the source electrode 9 of the MOSFET element 2. Note that the thin metal film 32 may be formed by use of a vapor deposition method. By utilizing solder wettability of the solder paste 27, the source electrode 9 of the MOSFET element 2 and the conductive plate 24 can be fixed to each other with good positional accuracy. Moreover, the lead 17 drawn out of the conductive plate 24 is bent downward in the vicinity of the MOSFET element 2, and is positioned on substantially the same plane as that of the die pad 5. The leads 13 and 17 are drawn out from a side surface of the one package 12.

As shown in FIG. 2B, the drain electrodes 26, 28 and 29 of the respective MOSFET elements 2 to 4 are fixed to the upper surface of the die pad 5 by use of the conductive paste 25. As shown in FIG. 2B, when a semiconductor wafer (not shown) is diced to separate semiconductor chips from each other, dicing is not performed between the MOSFET elements 2 and 3 and between the MOSFET elements 3 and 4. As a result, the MOSFET elements 2 to 4 are set in the integrated state, and thus are handled as one chip. Accordingly, the MOSFET elements 2 to 4 can be fixed to the upper surface of the die pad 5 in one die-bonding step.

By use of the solder pastes 27, 30 and 31, the conductive plate 24 is fixed to the upper surfaces of the respective source electrodes 9 to 11 of the MOSFET elements 2 to 4. As described above, on the bonded surface of the conductive plate 24, the thin metal films 32 to 34 having high solder wettability are formed, by use of the plating method or the like, at least in the regions fixed to the source electrodes 9 to 11 of the MOSFET elements 2 to 4, respectively. By utilizing solder wettability of the solder pastes 27, 30 and 31, the source electrodes 9 to 11 of the MOSFET elements 2 to 4 and the conductive plate 24 can be fixed to each other with good positional accuracy. In this structure, the conductive plate 24 has a flat-plate shape, and the thickness of the one package 12 (indicated by the dotted line) can be reduced.

In each of FIGS. 3A and 3B, the X axis shows the current amount in a MOSFET chip, and the Y axis shows power-conversion energy efficiency in a case where the MOSFET chip is used in a DC-DC converter circuit. Note that the chip in FIG. 3A is a chip formed of one MOSFET element.

In FIG. 3A, the dotted line shows a case where one MOSFET chip having a small chip size (small capacity) is used in the DC-DC converter circuit, and the dashed line shows a case where one MOSFET chip having a large chip size (large capacity) is used in the DC-DC converter circuit. Note that the chip size (area) of the large chip indicated by the dashed line is about three times larger than the chip size of the small chip indicated by the dotted line.

As indicated by the dotted line, in the case where the MOSFET chip having the small chip size is used, the power-conversion energy efficiency is high in a low current region since a capacity value is small. In contrast, the power-conversion energy efficiency is low in a large current region since an on-resistance value is large. As indicated by the dashed line, in the case where the MOSFET chip having the large chip size is used, the power-conversion energy efficiency is low in the low current region since a capacity value is large. In contrast, the power-conversion energy efficiency is high in the large current region since an on-resistance value is small.

In FIG. 3B, the solid line represents this embodiment. FIG. 3B shows a case where a plurality of MOSFET elements, which can be individually driven, are used in the DC-DC converter circuit. In this embodiment, as described above, the three MOSFET elements 2 to 4 (see FIG. 1) are connected to one another in parallel, and a gate voltage can be individually applied to each of the gate electrodes 6 to 8 in the MOSFET elements 2 to 4. The above structure makes it possible to set the power-conversion energy efficiency high by driving only the MOSFET element 2 in the low current region of the DC-DC converter circuit. Next, by driving the MOSFET element 3 in the state where the MOSFET element 2 is driven, the power-conversion energy efficiency can be set high in an intermediate current region of the DC-DC converter circuit. Lastly, by driving the MOSFET element 4 in the state where the MOSFET elements 2 and 3 are driven, the power-conversion energy efficiency can be set high in the large current region of the DC-DC converter circuit.

Specifically, as described with reference to FIG. 3A, driving of the MOSFET elements 2 to 4 is adjusted in accordance with the current regions of the DC-DC converter circuit. This adjustment allows the power-conversion energy efficiency to remain high, as shown in FIG. 3B.

Incidentally, in this embodiment, the description has been given of the case where the die pad 5 and the conductive plate 24 are formed of the Cu frame. However, the preferred embodiment of the present invention is not limited to this case. For example, instead of the Cu frame, a frame mainly made of Fe—Ni or made of other metal materials may be used. Moreover, in this embodiment, the description has been given of the structure in which three MOSFET elements are used as one chip, and are sealed in one package. However, the preferred embodiment of the present invention is not limited to this structure. For example, four or more MOSFET elements may be sealed in one package, and be individually driven. Moreover, in this embodiment, the description has been given of the case where three MOSFET elements having the same cell structure and the same element size are used. However, the preferred embodiment of the present invention is not limited to this case. For example, semiconductor elements having the same cell structure and different element sizes may be sealed in one package. Furthermore, in this embodiment, the description has been given of the case where the thin metal films 32 to 34 are formed on the conductive plate 24. However, the preferred embodiment of the present invention is not limited to this case. For example, in a case where the conductive plate 24 is fixed in a state where the solder pastes 27, 30 and 31 are respectively applied onto the source electrodes 9 to 11, the same effect can be achieved even if the thin metal films 32 to 34 are not formed on the conductive plate 24. Besides the above, various changes can be made without departing from the scope of the preferred embodiment of the present invention.

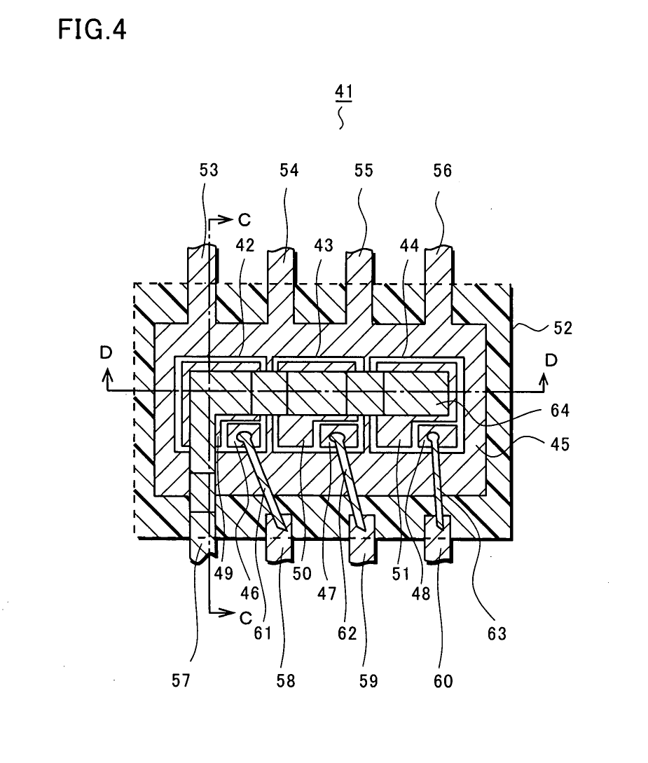

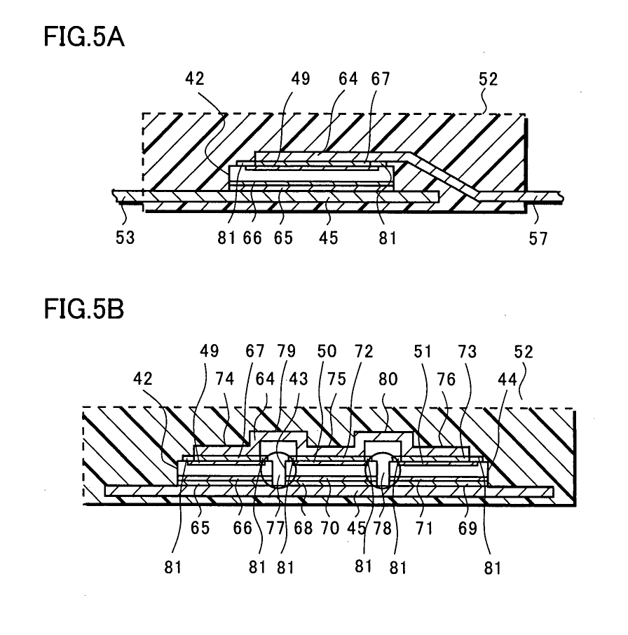

Next, with reference to FIGS. 4 and 5, a semiconductor device according to another preferred embodiment of the present invention will be described in detail. FIG. 4 is a plan view for explaining the semiconductor device according to this embodiment. FIG. 5A is a cross-sectional view taken along the line C-C in the semiconductor device shown in FIG. 4. FIG. 5B is a cross-sectional view taken along the line D-D in the semiconductor device shown in FIG. 4. Note that, the above description of the power-conversion energy efficiency in the DC-DC converter circuit shown in FIGS. 3A and 3B will be referred to in description of the semiconductor device of this embodiment shown in FIGS. 4 and 5. Incidentally, FIG. 4 does not show a passivation film shown in FIGS. 5A and 5B.

As shown in FIG. 4, in a semiconductor device 41 of this embodiment, for example, three MOSFET chips 42 to 44 are fixed to a die pad 45 by use of a conductive adhesive, for example, a conductive paste 65 (see FIG. 5A) which is a solder paste, a silver paste or the like. The MOSFET chips 42 to 44 have the same cell structure and the same element size. On a front surfaces of the respective chips, gate electrodes 46 to 48 and source electrodes 49 to 51 are formed. Moreover, on a rear surfaces of the chips, drain electrodes 66, 70 and 71 (see FIG. 5B) are formed. Furthermore, the dotted line shows an external shape of one package 52, and leads 53 to 60 are drawn out of the one package 52, and are then used as external terminals. Specifically, in the semiconductor device 41, a plurality of semiconductor elements, for example, the three MOSFET chips 42 to 44 are sealed in the one package 52.

The die pad 45 and the leads 53 to 60 are formed by processing a copper (Cu) lead frame (hereinafter called a Cu frame). The leads 53 to 56 are formed as being continuous with the die pad 45. The die pad 45 is fixed to the drain electrodes 66, 70 and 71 in the MOSFET chips 42 to 44, and the leads 53 to 56 are used as drain terminals. Although the MOSFET chips 42 to 44 respectively have the independent drain electrodes 66, 70 and 71, a common potential is applied to the drain electrodes 66, 70 and 71 with the die pad 45.

The gate electrode 46 in the MOSFET chip 42 is electrically connected to the lead 58 with a thin metal wire 61, and the lead 58 is used as a gate terminal. Similarly, the gate electrodes 47 and 48 in the MOSFET chips 43 and 44 are electrically connected to the leads 59 and 60 with thin metal wires 62 and 63, respectively. The leads 59 and 60 are used as gate terminals.

The source electrodes 49 to 51 in the MOSFET chips 42 to 44 are fixed to a conductive plate 64 made of a conductive material, such as the Cu frame, by use of a conductive adhesive, for example, solder pastes 67, 72 and 73 (see FIG. 5B) which are solder pastes, silver pastes or the like. Although the MOSFET chips 42 to 44 respectively have the individually independent source electrodes 49 to 51, a common potential is applied to the source electrodes 49 to 51 with the conductive plate 64. Moreover, the lead 57 drawn out of the conductive plate 64 is used as a source terminal.

The structure described above makes it possible to apply common drain potential and common source potential to the MOSFET chips 42 to 44 sealed in the one package 52. Meanwhile, gate potential can be respectively applied to the MOSFET chips 42 to 44. As a result, the MOSFET chips 42 to 44 in the one package 52 can be individually driven. Thus, it is possible to improve efficiency (see the above descriptions for FIGS. 3A and 3B) by controlling the amount of currents outputted from the one package 52.

As shown in FIG. 5A, the drain electrode 66 of the MOSFET chip 42 is fixed to an upper surface of the die pad 45 by use of a conductive paste 65. Moreover, on an upper surface of the MOSFET chip 42, a passivation film 81 made of, for example, a silicon nitride film (SiN) is formed. The source electrode 49 of the MOSFET chip 42 is exposed from an opening provided in the passivation film 81. Moreover, by use of the conductive paste 67, the conductive plate 64 is fixed to the upper surface of the source electrode 49 of the MOSFET chip 42. The lead 57 drawn out of the conductive plate 64 is bent downward in the vicinity of the MOSFET chip 42, and is positioned on substantially the same plane as that of the die pad 45. The leads 53 and 57 are drawn out from a side surface of the one package 52.

As shown in FIG. 5B, the drain electrodes 66, 70 and 71 of the respectively MOSFET chips 42 to 44 are fixed to the upper surface of the die pad 45 by use of the conductive pastes 65, 68 and 69. Moreover, by use of the conductive pastes 67, 72 and 73, the conductive plate 64 is fixed to the upper surfaces of the source electrodes 49 to 51 in the MOSFET chips 42 to 44. As shown in FIG. 5B, the conductive plate 64 has an uneven shape, and is fixed to the source electrodes 49 to 51 respectively in concave regions 74 to 76. Specifically, above a region 77 where the MOSFET chips 42 and 43 are separated from each other and above a region 78 where the MOSFET chips 43 and 44 are separated from each other, convex regions 79 and 80 of the conductive plate 64 are respectively disposed. As a result, the conductive plate 64 and drain regions exposed to sides (circled regions) of the MOSFET chips 42 to 44 are not short-circuited with the conductive pastes 67, 72 and 73. Specifically, it is possible to prevent short-circuiting between sources and drains of the MOSFET chips 42 to 44. Note that the areas of the respective concave regions 74 to 76 of the conductive plate 64 are made wide as corresponding to regions where the source electrodes 49 to 51 are formed in the MOSFET chips 42 to 44. Thus, on-resistance values of the MOSFET chips 42 to 44 can be lowered.

As described with reference to FIGS. 3A and 3B, driving of the MOSFET chips 42 to 44 can be adjusted in accordance with the current regions of the DC-DC converter circuit, also in the structure in which the MOSFET chips 42 to 44 are individually fixed to the upper surface of the die pad 45. This adjustment allows the power-conversion energy efficiency to remain high, as shown in FIG. 3B. Note that, in the description for FIG. 3B, the description has been given of the case where three MOSFET elements are used as one chip. Meanwhile, the same effect can be achieved also in a case of using three semiconductor chips (a structure in which one semiconductor element is formed on each of the semiconductor chips) as shown in FIG. 4.

Note that, in this embodiment, the description has been given of the case where the die pad 45 and the conductive plate 64 are formed of the Cu frame. However, the preferred embodiment of the present invention is not limited to this case. For example, instead of the Cu frame, a frame mainly made of Fe—Ni, or made of other metal materials may be used. Moreover, in this embodiment, the description has been given of the structure in which three MOSFET chips are sealed in one package. However, the preferred embodiment of the present invention is not limited to this structure. For example, four or more MOSFET chips may be sealed in one package, and be individually driven. Furthermore, in this embodiment, the description has been given of the case where three MOSFET chips having the same cell structure and the same chip size are used. However, the preferred embodiment of the present invention is not limited to this case. For example, semiconductor elements having the same cell structure and different chip sizes may be sealed in one package. Besides the above, various changes can be made without departing from the scope of the preferred embodiment of the present invention.

In the preferred embodiment of the present invention, a common conductive plate is fixed to a main electrodes of respective plurality of semiconductor elements. Moreover, potential can be respectively applied to the control electrodes of the plurality of semiconductor elements by individual conductive members. This structure allows the plurality of semiconductor elements to be individually driven. For example, high efficiency in power supply for energy conversion is maintained by using a semiconductor device in a DC-DC converter circuit.

Moreover, in the preferred embodiment of the present invention, the conductive plate has a flat plate shape. Regions excellent in solder wettability are formed on the conductive plate. This structure makes it possible to use the self-alignment technique utilizing a solder wettability, and to reduce a thickness of the one package.

Moreover, in the preferred embodiment of the present invention, a plurality of concave parts are formed on the conductive plate as respectively corresponding to the main electrodes of the semiconductor chips. This structure makes it possible to prevent short-circuiting of the semiconductor chips while avoiding short-circuiting between the conductive plate and drain regions exposed to side surfaces of the semiconductor chips.

Moreover, in the preferred embodiment of the present invention, the plurality of semiconductor elements are sealed in one package. The plurality of semiconductor elements are integrally connected to one another to form one chip. This structure makes it possible to fix the plurality of semiconductor elements in one die-bonding step.

Moreover, in the preferred embodiment of the present invention, thin metal wires are connected to the control electrodes of the plurality of semiconductor elements on a one-to-one basis. This structure allows the plurality of semiconductor elements to be individually driven.

What is claimed is:

1. A semiconductor device having a plurality of semiconductor elements sealed in one package in an integrally connected state, in which device a main electrode mainly supplying a principal current and a control electrode sending and receiving a control signal are formed at one principal surface of each of the semiconductor elements, comprising:
a conductive plate connected integrally to the main electrodes of the respective plurality of semiconductor elements; and
conductive members connected to the control electrodes of the plurality of semiconductor elements on a one-to-one basis.

2. A semiconductor device having a plurality of semiconductor chips sealed in one package, in which device a main electrode that mainly supplies a principal current and a control electrode that sends and receives a control signal are formed at one principal surface of each of the semiconductor chip, comprising:
a conductive plate connected integrally to the main electrodes of the respective plurality of semiconductor chips; and
conductive members connected to the control electrodes of the plurality of semiconductor chips on a one-to-one basis.

3. The semiconductor device according to claim 1, wherein the conductive plate has a flat-plate shape.

4. The semiconductor device according to claim 3, wherein the conductive plate has solder wettability only in a region where the conductive plate is connected to the main electrodes of the semiconductor elements.

5. The semiconductor device according to claim 2, wherein
a plurality of concave and convex shapes are formed in the conductive plate, and
the main electrodes of the semiconductor chips are connected to concave regions of the conductive plate.

6. The semiconductor device according to any one of claims 1 and 2, wherein the conductive plate is a copper plate.

7. The semiconductor device according to any one of claims 1 and 2, wherein the conductive members are thin metal wires.
